(19) United States
(12) Patent Application Publication
(10) Pub. No.: US 2024/0322095 A1
(43) Pub. Date: Sep. 26, 2024

(54) LIGHT-EMITTING DEVICE AND MANUFACTURING METHOD OF LIGHT-EMITTING DEVICE

(71) Applicant: NICHIA CORPORATION, Anan-shi (JP)

(72) Inventors: Kazuya TAMURA, Anan-shi (JP); Takeshi KUSUSE, Tokushima-shi (JP)

(73) Assignee: NICHIA CORPORATION, Anan-shi (JP)

(21) Appl. No.: 18/612,487

(22) Filed: Mar. 21, 2024

(30) Foreign Application Priority Data
Mar. 22, 2023 (JP) 2023-044913

(51) Int. Cl. H01L 33/60

(52) U.S. Cl. CPC H01L 33/60; H01L 2933/0058

(57) ABSTRACT

A light-emitting device includes a package having a recessed portion, a light-emitting element placed on a bottom surface of the recessed portion at a position away from an inner lateral surface of the recessed portion, and a light-reflective member disposed between the light-emitting element and the inner lateral surface so as to surround the light-emitting element at a position away from the light-emitting element and having a light reflecting surface configured to reflect light emitted from the light-emitting element. The light reflecting surface is inclined with respect to the bottom surface in a direction from the inner lateral surface toward the light-emitting element, and has different light reflection characteristics at different positions with different heights from the bottom surface to the light reflecting surface.

### CROSS-REFERENCE TO RELATED APPLICATIONS

This application claims priority to Japanese Patent Application No. 2023-044913, filed on Mar. 22, 2023, the disclosure of which is hereby incorporated herein by reference in its entirety.

### BACKGROUND

The present invention relates to a light-emitting device and a manufacturing method of a light-emitting device.

In the related art, in order to improve efficiency of extracting light emitted from a light-emitting element included in a light-emitting device, a light-reflective member is used to reflect light emitted from the light-emitting element. For example, Japanese Unexamined Patent Application Publication No. 2008-098247 discloses a light-emitting device including a tapered light reflecting board for reflecting upwardly light emitted laterally from a light-emitting element.

### SUMMARY

The light reflecting board disclosed in the Japanese Unexamined Patent Application Publication No. 2008-098247 has a reflection film made of a metal film formed by, for example, sputtering, vapor deposition, plating, or the like. However, the reflection film made of the metal film has uniform light reflection characteristics, and when light emitted from the light-emitting element is reflected by such a reflection film, luminance spots may occur.

There is a need to provide a light-emitting device that can reduce luminance spots of emitted light.

A light-emitting device according to an embodiment includes a package including a recessed portion, a light-emitting element placed on a bottom surface of the recessed portion at a position away from an inner lateral surface of the recessed portion, and a light-reflective member disposed between the light-emitting element and the inner lateral surface so as to surround the light-emitting element at a position away from the light-emitting element and including a light reflecting surface configured to reflect light emitted from the light-emitting element, wherein the light reflecting surface is inclined with respect to the bottom surface in a direction from the inner lateral surface toward the light-emitting element, and has different light reflection characteristics at different positions with different heights from the bottom surface to the light reflecting surface.

A method of manufacturing a light-emitting device according to an embodiment includes preparing a package including a recessed portion including an inner lateral surface and a bottom surface having a placement region on which a light-emitting element is placeable; mixing at least first particles comprising a light reflecting material and second particles having a smaller average particle diameter than the first particles, a lower average aspect ratio than the first particles, and a lower total reflectance than the first particles to prepare a mixture having thixotropy; applying the mixture to at least one of the bottom surface or the inner lateral surface; and curing the mixture to form a light-reflective member including a light reflecting surface inclined with respect to the bottom surface in a direction from the inner lateral surface toward the placement region so as not to reach the placement region.

In accordance with the light-emitting device according to the embodiment, the light reflecting surface that reflects light emitted from the light-emitting element is inclined in a direction from the inner lateral surface of the recessed portion toward the light-emitting element, and the light reflection characteristics of the light reflecting surface vary depending on a height from the bottom surface of the recessed portion to the light reflecting surface. Consequently, since the light reflecting surface has no uniform light reflection characteristics like a metal film, for example, and has different light reflection characteristics depending on the height from the bottom surface of the recessed portion to the light reflecting surface, so that luminance spots of light emitted from the light-emitting device can be reduced.

### BRIEF DESCRIPTION OF THE DRAWINGS

FIG. 1 is a schematic perspective view illustrating an example of a light-emitting device 1 according to an embodiment of the present disclosure.

FIG. 2 is a schematic plan view illustrating an example of a light-emitting device 1 according to an embodiment of the present disclosure.

FIG. 3 is a schematic cross-sectional view taken along line III-III illustrated in FIG. 2.

FIG. 4 is a cross-sectional view schematically illustrating an example of a light-reflective member 5.

FIG. 5 is an enlarged view schematically illustrating a portion V in FIG. 4.

FIG. 6 is an enlarged view schematically illustrating a portion VI in FIG. 4.

FIG. 7 is a schematic plan view illustrating a light-emitting device 1 according to a modified example.

FIG. 8 is a schematic cross-sectional view taken along line VIII-VIII illustrated in FIG. 7.

FIG. 9 is a flowchart illustrating an example of a manufacturing method of a light-emitting device 1 according to an embodiment of the present application.

FIG. 10 is a perspective view illustrating an example of step S3 of applying a mixture 7 to a package 2.

### DETAILED DESCRIPTION

An embodiment of the present invention is described below with reference to the drawings. Note that a light-emitting device 1 and a manufacturing method of the light-emitting device 1 according to the present embodiment are intended to embody the technical concepts of the present invention, and the present invention is not limited to the following unless specifically stated. The sizes and positional relationships of members illustrated in the drawings may be appropriately exaggerated, or some of the members may be simplified or omitted.

In the present embodiment, XYZ orthogonal coordinates are employed for convenience of explanation. Specifically, a thickness direction of a light-emitting element 3 (details are described below) included in the light-emitting device 1 is referred to as a “Z axis”, and two directions respectively orthogonal to the thickness direction are referred to as an “X axis” and a “Y axis”. In the Z-axis, a direction on a side where light from the light-emitting device 1 mainly travels is referred to as “up”, and an opposite direction thereof is referred to as “down”. However, the expression of “up” and “down” is for convenience and is independent of the direction of gravity. An expression “in plan view” used in the present specification is assumed to indicate a case when viewed from above on the Z axis to below.

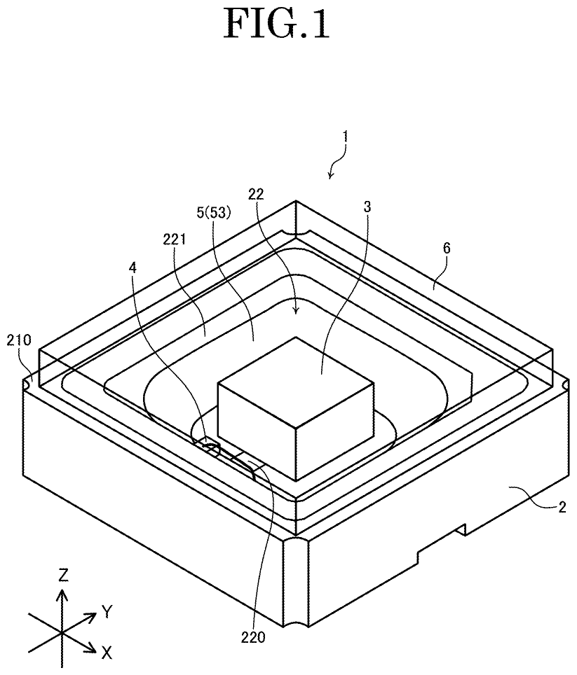

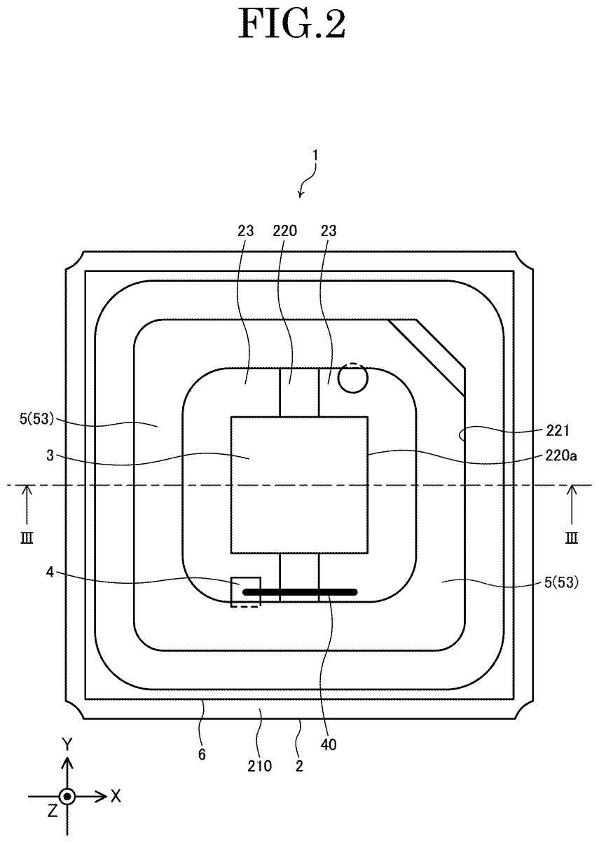

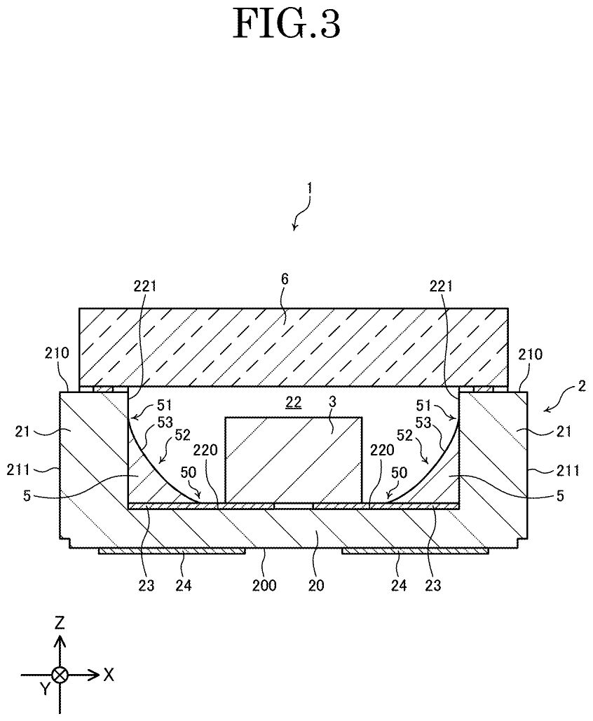

FIG. 1 is a schematic perspective view illustrating an example of the light-emitting device 1 according to an embodiment. FIG. 2 is a schematic plan view illustrating an example of the light-emitting device 1 according to an embodiment. FIG. 3 is a schematic cross-sectional view taken along line III-III illustrated in FIG. 2.

The light-emitting device 1 according to the present embodiment includes a package 2 having a recessed portion 22 on an upper surface 210 side, the light-emitting element 3 placed on a bottom surface 220 of the recessed portion 22 at a position away from an inner lateral surface 221 of the recessed portion 22, a protective element 4 placed on the bottom surface 220 of the recessed portion 22 at a position away from the light-emitting element 3 and the inner lateral surface 221 of the recessed portion 22, a light-reflective member 5 disposed between the light-emitting element 3 and the inner lateral surface 221 of the recessed portion 22 so as to surround the light-emitting element 3 at a position away from the light-emitting element 3 and having a light reflecting surface 53 for reflecting light emitted from the light-emitting element 3, and a cap 6 bonded to the upper surface 210 of the package 2 so as to close the recessed portion 22.

### Package 2

The package 2 includes a base portion 20 having a flat plate shape and a lateral wall portion 21 disposed on the base portion 20. The recessed portion 22 of the package 2 is formed by the base portion 20 and the lateral wall portion 21.

The base portion 20 and the lateral wall portion 21 mainly comprise or are mainly formed of an insulating base material. Examples of the material of the insulating base material include ceramics, glass epoxy, and resin. Examples of the ceramics include alumina, aluminum nitride, and mullite. The base portion 20 and the lateral wall portion 21 may be integrated with each other or may be separated from each other.

The lateral wall portion 21 has a rectangular frame shape in plan view. Note that the lateral wall portion 21 may have no rectangular frame shape in plan view. The recessed portion 22 has the bottom surface 220 and the inner lateral surface 221. The bottom surface 220 of the recessed portion 22 corresponds to a portion of an upper surface of the base portion 20 surrounded by the upper surface 210 of the lateral wall portion 21 in plan view. The bottom surface 220 of the recessed portion 22 has a placement region 220a on which the light-emitting element 3 can be placed. The inner lateral surface 221 of the recessed portion 22 corresponds to an inner surface of the lateral wall portion 21. Note that the recessed portion 22 may have a step. Furthermore, the bottom surface 220 and the inner lateral surface 221 of the recessed portion 22 may be covered with a protective film for preventing deterioration.

The package 2 includes positive and negative first wirings 23 on the bottom surface 220 of the recessed portion 22 (the upper surface of the base portion 20) and positive and negative second wirings 24 on a lower surface 200 of the base portion 20. The first wiring 23 and the second wiring 24 are connected to each other by, for example, an internal wiring penetrating the base portion 20. Each of the positive and negative first wirings 23 is disposed in a range including the placement region 220a, and the light-emitting element 3 is bonded thereto. The second wiring 24 is bonded to a pad of a mounting substrate when the light-emitting device 1 is surface-mounted. The first wiring 23 and the second wiring 24 are formed using, for example, a metal such as copper, aluminum, gold, silver or the like.

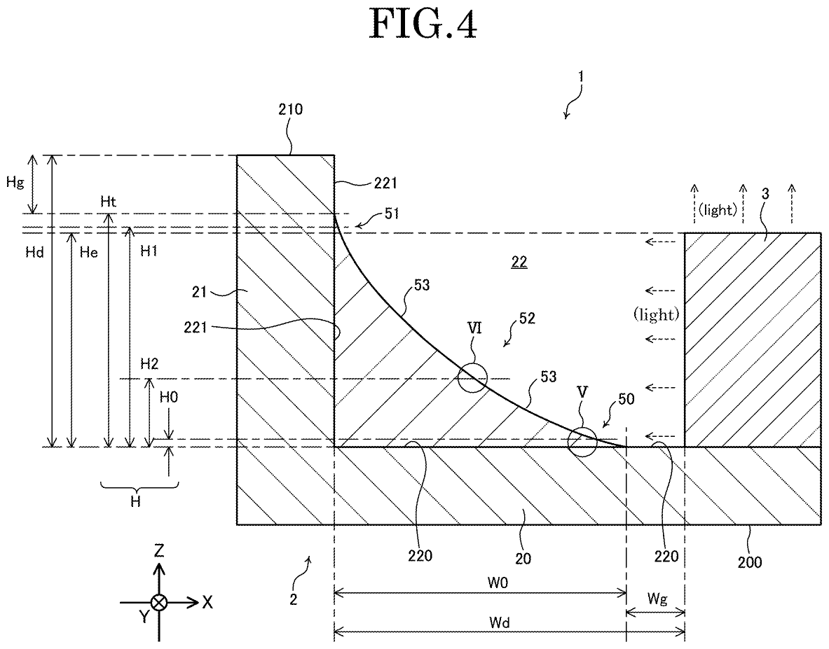

The dimensions of each part of the package 2 are appropriately determined in accordance with, for example, the dimensions and the like of the light-emitting element 3. The length of each side of the package 2 in plan view is, for example, in a range from 0.3 mm to 10 mm. The height of the package 2 is, for example, in a range from 0.1 mm to 4 mm. The depth (height Hd in FIG. 4) of the recessed portion 22 is, for example, in a range from 0.075 mm to 3 mm.

### Light-Emitting Element 3

The light-emitting element 3 is an element that emits light having a predetermined wavelength. The light-emitting element 3 emits ultraviolet light or blue light, for example. The light-emitting element 3 mainly emits light from an upper surface thereof, but also emits light from a lateral surface thereof (may be a part thereof). The light-emitting element 3 may also emit light from a lower surface thereof (may be a part thereof). In the present embodiment, the light-emitting device 1 is described as a light-emitting device including one light-emitting element 3, but may include a plurality of light-emitting elements 3.

Examples of the light-emitting element 3 that can be used include a light-emitting diode and a laser diode. The light-emitting element 3 includes at least a semiconductor layer including an n-type semiconductor layer, a p-type semiconductor layer, a light-emitting device layer, and the like, and positive and negative electrodes. The light-emitting element 3 preferably uses a nitride semiconductor layer containing, for example, In_{X}Al_{Y}Ga_{1-X-Y}N (0≤X, 0≤Y, X+Y≤1).

The emission peak wavelength of light emitted by the light-emitting element 3 is in a range from 260 nm to 630 nm, for example; however, no such limitation is intended. The emission peak wavelength of the light-emitting element 3 that emits ultraviolet light may be, for example, in an ultraviolet region from or below 400 nm or in a deep ultraviolet region from or below 280 nm. By using the light-emitting element 3 that emits ultraviolet light, for example, the light-emitting device 1 can be used as a light source for sterilization, disinfection, or the like.

The light-emitting element 3 is placed on the bottom surface 220 of the recessed portion 22 (upper surface of the base portion 20) at a position away from the inner lateral surface 221 of the recessed portion 22. In the present embodiment, the light-emitting element 3 is placed on the placement region 220a of the bottom surface 220. The placement region 220a is provided at the center of the bottom surface 220. The placement region 220a includes the center of the bottom surface 220. The light-emitting element 3 is flip-chip mounted on the package 2. Specifically, the light-emitting element 3 includes the positive and negative electrodes (not illustrated) on the same surface side, and the positive and negative electrodes are electrically connected to the positive and negative first wirings 23 by conductive members, respectively. Examples of the conductive member that can be used include a conductive paste containing solder, copper, gold, palladium, or the like, and a bump containing silver, gold, or the like.

Note that, instead of the above flip-chip mounting, the light-emitting element 3 may be face-up mounted on the package 2 and the positive and negative electrodes may be connected to the positive and negative first wirings 23 by wires, respectively. The light-emitting element 3 may have one of the positive and negative electrodes on the upper surface thereof and the other electrode on the lower surface thereof. In such a case, the electrode on the upper surface may be connected to one of the positive and negative first wirings 23 by a conductive member, and the electrode on the lower surface may be connected to the other first wiring 23 by a wire.

The light-emitting element 3 is rectangular in plan view. The length of each side of the light-emitting element 3 in plan view is, for example, in a range from 100 μm to 3000 μm. The thickness (height He in FIG. 4) of the light-emitting element 3 is, for example, in a range from 50 μm to 2000 μm. Note that the shape of the light-emitting element 3 in plan view may be, for example, a polygon such as a triangle or a hexagon; however, no such limitation is intended.

### Protective Element 4

The protective element 4 is an element for protecting the light-emitting element 3 from a surge voltage or static electricity. Examples of the protective element 4 that can be used include a Zener diode. The protective element 4 is electrically connected in parallel with the light-emitting element 3, for example. In the present embodiment, the light-emitting device 1 is described as including one protective element 4, but may include a plurality of light-emitting elements 3 or may not include the protective element 4.

The protective element 4 is placed on the bottom surface 220 of the recessed portion 22 (upper surface of the base portion 20) at a position away from the light-emitting element 3 and the inner lateral surface 221 of the recessed portion 22. In the present embodiment, the lower surface of the protective element 4 is connected to one of the positive and negative first wirings 23 by a conductive member, and the upper surface of the protective element 4 is connected to the other first wiring 23 by a wire 40.

### Light-Reflective Member 5

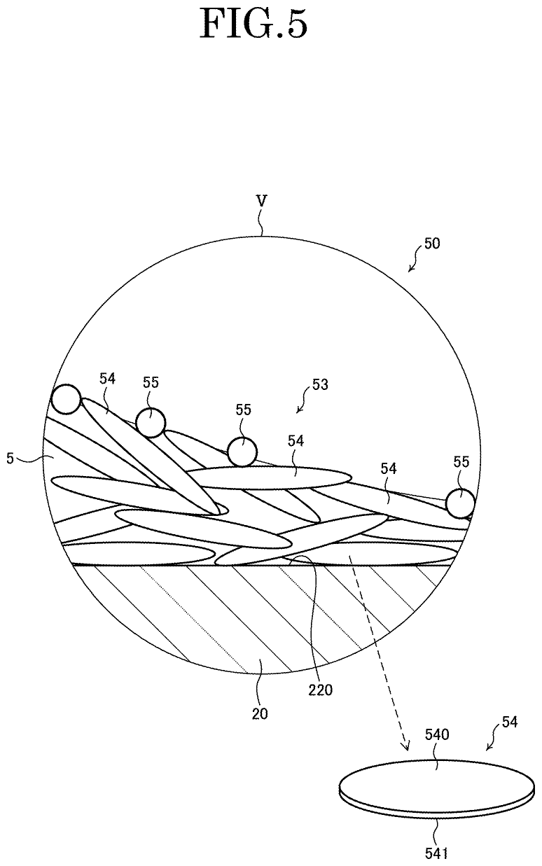

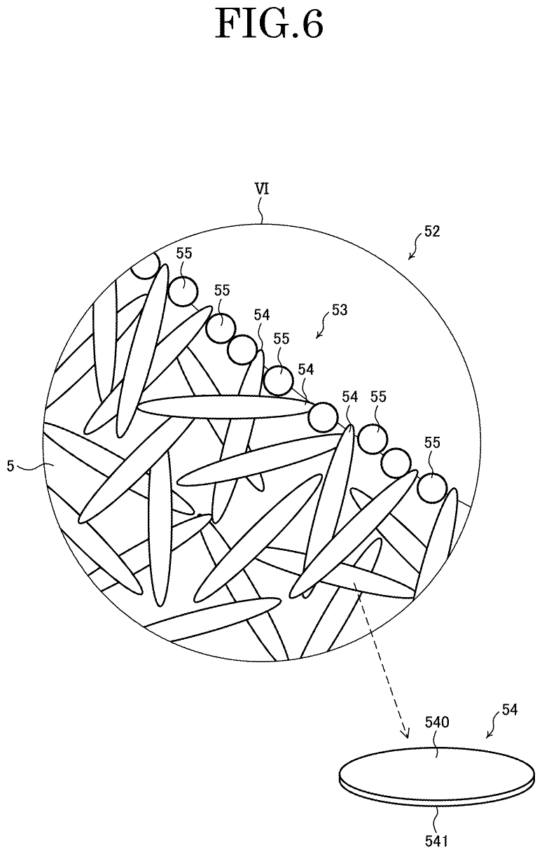

FIG. 4 is a cross-sectional view schematically illustrating an example of the light-reflective member 5. FIG. 5 is an enlarged view schematically illustrating a portion V in FIG. 4. FIG. 6 is an enlarged view schematically illustrating a portion VI in FIG. 4.

The light-reflective member 5 is a member having light reflectivity that reflects light emitted from the light-emitting element 3. The light-reflective member 5 is disposed between the light-emitting element 3 and the inner lateral surface 221 of the recessed portion 22 so as to surround the light-emitting element 3 at a position away from the light-emitting element 3. At this time, the light-reflective member 5 is formed in contact with the bottom surface 220 and the inner lateral surface 221 of the concave portion 22. The light-reflective member 5 is formed in a frame shape along the inner lateral surface 221 of the recessed portion 22 (inner surface of the lateral wall portion 21) in plan view. Note that as illustrated in FIG. 2, the light-reflective member 5 may cover a part of the protective element 4 or may cover the entire protective element 4. The light-reflective member 5 may not cover the protective element 4.

The light-reflective member 5 includes an inner peripheral edge portion 50 formed on a side close to the light-emitting element 3, an outer peripheral edge portion 51 formed on a side close to the inner lateral surface 221 of the recessed portion 22, and an intermediate portion 52 located between the inner peripheral edge portion 50 and the outer peripheral edge portion 51. The light-reflective member 5 includes the light reflecting surface 53 that is an outer surface of the light-reflective member 5. The light reflecting surface 53 is provided over the inner peripheral edge portion 50, the intermediate portion 52, and the outer peripheral edge portion 51. Note that the intermediate portion 52 may be located between the inner peripheral edge portion 50 and the outer peripheral edge portion 51, does not necessarily need to be located at the center between the inner peripheral edge portion 50 and the outer peripheral edge portion 51, and may be specified at an approximate position. The inner peripheral edge portion 50 and the outer peripheral edge portion 51 do not necessarily need to be located on peripheral edges, and may be specified at approximate positions. Moreover, the inner peripheral edge portion 50, the intermediate portion 52, and the outer peripheral edge portion 51 may be defined as regions each having a predetermined width. In such a case, the inner peripheral edge portion 50, the intermediate portion 52, and the outer peripheral edge portion 51 may be separated from one another with a gap or may be separated with no gap.

The light reflecting surface 53 reflects upwardly light emitted from the light-emitting element 3. The reflectance of the light reflecting surface 53 is preferably 60% or more, more, preferably 85% or more, with respect to the emission peak wavelength of the light-emitting element 3.

The light reflecting surface 53 is inclined with respect to the bottom surface 220 of the recessed portion 22 in a direction from the inner lateral surface 221 of the recessed portion 22 toward the light-emitting element 3. In a case in which a height from the bottom surface 220 to the light reflecting surface 53 is defined as a height H of the light reflecting surface 53, when a height of the light reflecting surface 53 in the inner peripheral edge portion 50 is defined as H0, a height of the light reflecting surface 53 in the outer peripheral edge portion 51 is defined as H1, and a height of the light reflecting surface 53 in the intermediate portion 52 is defined as H2, a relationship of H0<H2<H1 is satisfied. As a distance from the light-emitting element 3 to the light reflecting surface 53 (distance in a left-right direction in FIGS. 3 and 4) increases, the height H of the light reflecting surface 53 increases. That is, the height H of the light reflecting surface 53 increases from the inner peripheral edge portion 50 toward the intermediate portion 52, and from the intermediate portion 52 toward the outer peripheral edge portion 51. It can be said that the height H of the light reflecting surface 53 is also the thickness of the light-reflective member 5, but in such a case, the thickness of the light-reflective member 5 increases in the order of the inner peripheral edge portion 50, the intermediate portion 52, and the outer peripheral edge portion 51.

A distance WO from the inner lateral surface 221 to a distal end of the inner peripheral edge portion 50 is shorter than a distance Wd from this inner lateral surface 221 to the light-emitting element 3. The bottom surface 220 has a portion not in contact with the light-reflective member 5 in a region located around the light-emitting element 3, and a gap (distance Wg) exists between the light-emitting element 3 and the light-reflective member 5. The height H of the light reflecting surface 53 is maximum at an upper end of the outer peripheral edge portion 51, but a maximum height Ht of the light reflecting surface 53 is lower than the height Hd of the recessed portion 22. Therefore, the inner lateral surface 221 located on the upper surface 210 side has a portion not in contact with the light-reflective member 5, and a gap (distance Hg) exists between the upper surface 210 and an outer edge of the light-reflective member 5 in contact with the inner lateral surface 221. The distance Hg can exceed 0 and be equal to or less than ½ of the height Hd. Although FIG. 4 illustrates a case in which the maximum height Ht of the light reflecting surface 53 is higher than the height He of the light-emitting element 3, the maximum height Ht may be lower than the height He of the light-emitting element 3.

Note that when the inner peripheral edge portion 50, the intermediate portion 52, and the outer peripheral edge portion 51 are defined as regions each having a predetermined width, the maximum height and the minimum height of the light reflecting surface 53 are defined in each of the regions, and the maximum height and the minimum height are determined by the following values. The maximum height H0 of the inner peripheral edge portion 50 is equal to or less than ¼ of the maximum height Ht of the light reflecting surface 53. The minimum height H1 of the outer peripheral edge portion 51 is equal to or greater than ⅔ of the maximum height Ht of the light reflecting surface 53. The minimum height H2 of the intermediate portion 52 is greater than ¼ of the maximum height Ht of the light reflecting surface 53, and the maximum height H2 of the intermediate portion 52 is less than ⅔ of the maximum height Ht of the light reflecting surface 53. At this time, the region of the intermediate portion 52 may be defined so that the minimum height H2 of the intermediate portion 52 is equal to or greater than ⅓ of the maximum height Ht of the light reflecting surface 53 and the maximum height H2 of the intermediate portion 52 is equal to or less than ⅗ of the maximum height Ht of the light reflecting surface 53.

As illustrated in FIGS. 3 and 4, the light reflecting surface 53 is formed in a curved shape in cross-sectional view. In the present embodiment, the light reflecting surface 53 is described as being formed in a concave shape with respect to the bottom surface 220 of the recessed portion 22, but may be formed in a convex shape with respect to the bottom surface 220 of the recessed portion 22. The curvatures of the concave shape and the convex shape may not be constant, or may be a combination of the concave shape and the convex shape. Accordingly, a position where the height H of the light-reflective member 5 is maximum is not necessarily a position in contact with the inner lateral surface 221.

### Modified Example of Light-Reflective Member 5

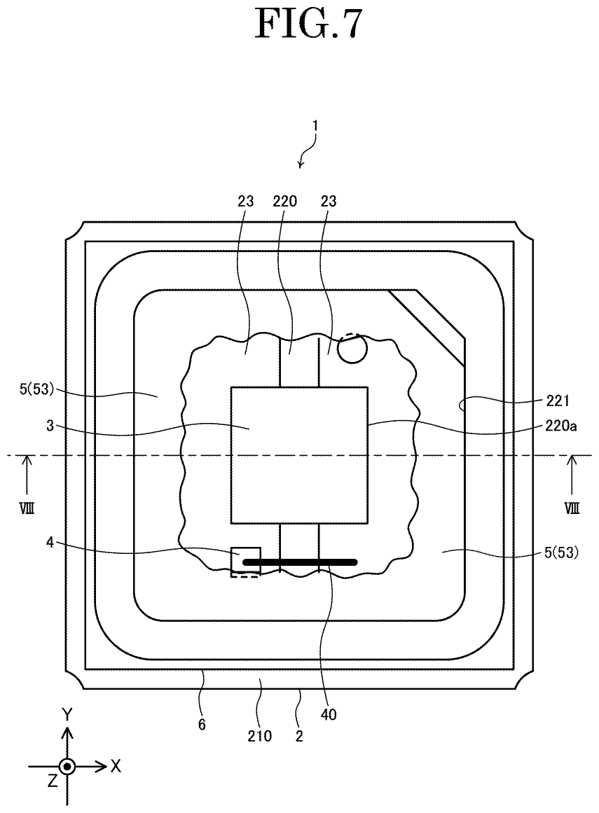

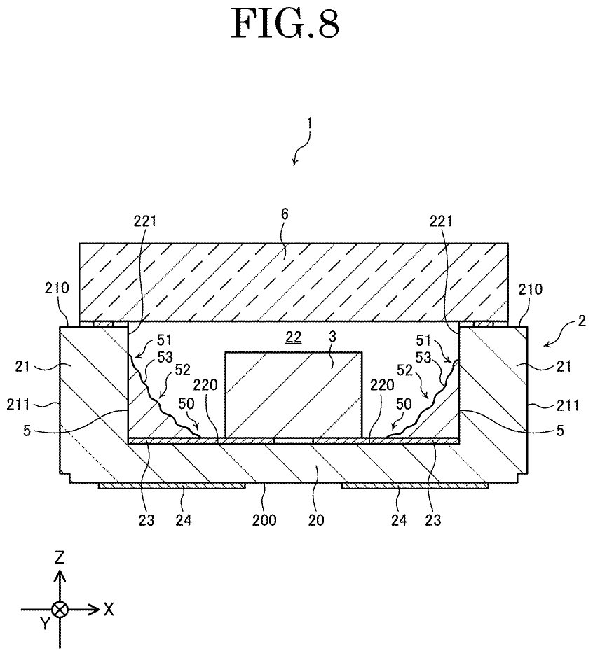

As a modified example of the light-reflective member 5, the light-reflective member 5 may be formed in an asymmetrical shape. FIG. 7 is a schematic plan view illustrating an example of the light-emitting device 1 according to a modified example. FIG. 8 is a schematic cross-sectional view taken along line VIII-VIII illustrated in FIG. 7. FIGS. 7 and 8 correspond to FIGS. 2 and 3, respectively, and are different in that the shape of the light-reflective member 5 is different, but the other configurations of the light-emitting device 1 are in common.

As illustrated in FIG. 7, the light-reflective member 5 according to the modified example can have an asymmetrical shape in plan view. As illustrated in FIG. 8, the light-reflective member 5 may have an asymmetrical shape in cross-sectional view. The asymmetrical shape has unevenness on the outer surface or the outer contour line thereof, and includes, for example, a distorted shape, which is not defined by a straight line or a curve having a constant curvature, in at least a part thereof. Therefore, the light-reflective member 5 is formed in a shape at least partially including a shape not defined by line symmetry or point symmetry in plan view or cross-sectional view as an asymmetrical shape. For example, although the inner peripheral edge portion 50 is formed to be separated from the light-emitting element 3 and to surround the periphery of the light-emitting element 3 in plan view, the shape of the inner edge surrounding the light-emitting element 3 in plan view may not be a rectangular shape such as a rectangle or a square. Although the outer peripheral edge portion 51 is formed along the inner lateral surface 221, the distance Hg may not be constant. The distance from the light reflecting surface 53 to the light-emitting element 3 at the same height may not be constant over the entire circumference surrounding the light-emitting element 3.

### Light Reflection Characteristics of Light-Reflective Member

The light reflecting surface 53 has different light reflection characteristics at positions where the height H (see FIG. 4) from the bottom surface 220 of the recessed portion 22 to the light reflecting surface 53 is different. The light reflection characteristics of the light reflecting surface 53 change from a position close to the light-emitting element 3 toward a position far from the light-emitting element 3 in a planar direction (for example, X direction or Y direction). The light reflection characteristics of the light reflecting surface 53 substantially continuously change as a whole. The “substantially” used herein means that the presence of a partial small region where the light reflection characteristics do not change is allowed when viewed locally.

The light reflection characteristics of the light reflecting surface 53 in the inner peripheral edge portion 50 are different from the light reflection characteristics of the light reflecting surface 53 in the intermediate portion 52. The light reflection characteristics used herein include at least one of reflectance of light or a degree of diffusion of light (also referred to as a degree of light scattering). The light reflection characteristics used herein may also be defined as characteristics including at least the reflectance of light and the degree of diffusion of light. The reflectance of light reflected by the light reflecting surface 53 is higher in the inner peripheral edge portion 50 than in the intermediate portion 52. Light emitted from the light-emitting element 3 is diffused and reflected by the light reflecting surface 53. The intermediate portion 52 diffuses light at the light reflecting surface 53 more than the inner peripheral edge portion 50. That is, it can be said that the degree of diffusion of light by the light reflecting surface 53 is higher in the intermediate portion 52 than in the inner peripheral edge portion 50. The surface roughness of the light reflecting surface 53 is greater in the intermediate portion 52 than in the inner peripheral edge portion 50.

As an example of a material for implementing the above light reflection characteristics, the light-reflective member 5 may comprise or be formed of a material including at least first particles 54 made of a light reflecting material and second particles 55 having a lower reflectance than the first particles 54. The second particles are particles having a smaller average particle diameter and a lower average aspect ratio than the first particles 54. In the present embodiment, a case in which an inorganic material is used as the material of the light-reflective member 5 is mainly described, but an organic material may be used.

When the light-emitting element 3 that emits ultraviolet light is used, the light-reflective member 5 preferably comprises or is formed of an inorganic material. In this case, the light-reflective member 5 may further contain an alkali metal, a scattering material, or a composition other than these materials, in addition to the first particles 54 and the second particles 55.

As illustrated in FIGS. 5 and 6, the first particle 54 is a scale-like or plate-like particle having two opposing main surfaces 540 and 541. Note that the first particle 54 may be a primary particle, or a secondary particle obtained by aggregating a plurality of primary particles. The first particle 54 may also be a mixture of the primary particle and the secondary particle.

The first particles 54 comprise or are composed of, for example, at least one of boron nitride or alumina. Note that the first particles 54 may use another material as long as the material reflects light having the emission peak wavelength of the light-emitting element 3.

The average particle diameter of the first particles 54 is in a range from 0.6 μm to 43 μm, for example. The average aspect ratio of the first particles 54 is, for example, 10 or more, preferably in a range from 10 to 70. A method for calculating the average particle diameter and the average aspect ratio is described below.

The second particles 55 are particles having a smaller average particle diameter, a lower average aspect ratio, and a lower reflectance than the first particles 54.

The second particles 55 comprise or are composed of, for example, silica.

The average particle diameter of the second particles 55 is in a range from 0.1 μm to 10 μm, for example. For example, the average aspect ratio of the second particles 55 is in a range from 1 to 5, preferably in a range from 1 to 2. A method for calculating the average particle diameter and the average aspect ratio is described below.

An area or the number of particles per unit area occupied by the second particles 55 in the light reflecting surface 53 is smaller in the inner peripheral edge portion 50 (see FIG. 5) than in the intermediate portion 52 (see FIG. 6). This is because the first particles 54 have a larger average particle diameter and a higher average aspect ratio than the second particles 55.

In the inner peripheral edge portion 50 where the thickness of the light-reflective member 5 (height H of the light reflecting surface 53) is relatively small, as illustrated in FIG. 5, the first particles 54 tend to be arranged in a lying state so that the main surfaces 540 and 541 of the first particles 54 follow the bottom surface 220. This results in an increase in an area where the main surfaces 540 and 541 of the first particle 54 are exposed as the light reflecting surface 53. As a result, since a gap between the first particles 54 into which the second particles 55 enter is reduced, the area or the number of the second particles 55 filling the gap is relatively reduced.

On the other hand, in the intermediate portion 52 where the thickness of the light-reflective member 5 is larger than in the inner peripheral edge portion 50, as illustrated in FIG. 6, the first particles 54 are randomly arranged in an arbitrary direction, and variations in an angle formed by the main surfaces 540 and 541 of the first particles 54 and the light reflecting surface 53 are greater than in the inner peripheral edge portion 50. Therefore, compared to the inner peripheral edge portion 50, the area of the first particles 54 where the main surfaces 540 and 541 are exposed as the light reflecting surface 53 is smaller. As a result, since the gap between the first particles 54 into which the second particles 55 enter is increased, the area or the number of the second particles 55 filling the gap is relatively increased.

Since the first particles 54 have a higher reflectance than the second particles 55, it can be said that the reflectance of the light reflecting surface 53 per unit area is higher when the area where the first particles 54 are exposed is larger and the area where the second particles 55 are exposed is smaller as illustrated in FIG. 5 than when the area where the first particles 54 are exposed is smaller and the area where the second particles 55 are exposed is larger as illustrated in FIG. 6. Furthermore, since the smoothness of the light reflecting surface 53 is higher and the surface roughness is smaller when the main surfaces 540 and 541 of the scale-like or plate-like first particles 54 are exposed as illustrated in FIG. 5 than when the distal end of the scale-like or plate-like first particles 54 are exposed as illustrated in FIG. 6, it can be said that the degree of scattering is lower. Moreover, as illustrated in FIGS. 5 and 6, in the light reflecting surface 53 per unit area, since the number of the first particles 54 and the number of the first particles 54 each exposed are different, the difference in the number of the particles may also affect the smoothness and the surface roughness of the light reflecting surface 53.

The alkali metal is at least one of potassium or sodium. The alkali metal is a metal contained in an alkali solution used in a step of forming the light-reflective member 5. The alkali solution is a solution in which the alkali metal is dissolved in a solvent. For example, water can be used as the solvent. The alkali solution in such a case is a potassium hydroxide solution or a sodium hydroxide solution, for example.

The scattering material is, for example, at least one of zirconia or titania. The scattering material preferably has a smaller average particle diameter and a lower average aspect ratio than the first particles 54. When the light-emitting element 3 that emits ultraviolet light is used, zirconia that absorbs less light in the ultraviolet wavelength region is preferable. The light-reflective member 5 includes the scattering material, so that the light reflectance of the light-reflective member 5 can be improved.

The light-reflective member 5 is formed by curing a mixture obtained by mixing at least the powder of the first particles 54 and the powder of the second particles 55 in an alkali solution. For example, the content ratio of the first particles 54 and the second particles 55 included in the light-reflective member 5 is preferably in a range from 1:1 to 4:1 by weight ratio. The weight of the first particles 54 included in the light-reflective member 5 is, for example, in a range from one time to four times the weight of the second particles 55 included in the light-reflective member 5.

### Calculation Method of Average Particle Diameter

The average particle diameters of measurement targets (the first particles 54, the second particles 55, the scattering material, and the like) are measured using, for example, a scanning electron microscope. Specifically, the measurement target is attached to a tape or the like, and the surface of the tape is placed on a sample stage of the scanning electron microscope. The number of pixels of the scanning electron microscope is set to, for example, one million pixels, the magnification is set to, for example, 1000 times to 2000 times, and a predetermined number of (for example, 100) images of the measurement target are acquired by the scanning electron microscope. Subsequently, the particle diameter of each measurement target is measured with image analysis software. For example, when the measurement target is the first particle 54, the particle diameter of the first particle 54 is the maximum diameter of the diameters of the first particle 54 when viewed from any one of the main surfaces 540 and 541. Subsequently, the median diameter is calculated from the measured particle diameters of the measurement targets, and the calculated value is defined as the average particle diameter of the measurement target.

As another calculation method, an image of a cross-section obtained by cutting the light-reflective member 5 (performing mirror polishing) or an image of the outer surface (light reflecting surface 53) of the light-reflective member 5 is acquired by a scanning microscope, and a predetermined number of images of the measurement target are acquired. Subsequently, the particle diameter of each measurement target may be measured by the image analysis software, and the average particle diameter of the measurement target may be calculated in the same manner as described above. As still another calculation method, the average particle diameter of the measurement target may be calculated by measuring the particle size distribution of the measurement target by a laser diffraction method.

### Calculation Method of Average Aspect Ratio

The average aspect ratios of the measurement targets (the first particles 54, the second particles 55, the scattering material, and the like) are calculated by measuring the lateral widths and the thicknesses of the measurement targets or measuring the longitudinal dimensions and the lateral dimensions of the measurement targets by using, for example, a scanning electron microscope.

Specifically, an image of a cross-section obtained by cutting the light-reflective member 5 (performing mirror polishing) is acquired by a scanning microscope, and a measurement region including a predetermined number of (for example, 1000) cross-sections of the measurement target is selected. The number of pixels of the scanning microscope is set to, for example, 20 million pixels, and the magnification is set to, for example, 500 times to 3000 times. When the measurement target is the first particle 54, the cross section of the measurement target is a plane substantially perpendicular to the main surfaces 540 and 541. Subsequently, a lateral width (or longitudinal dimension) and a thickness (or lateral dimension) in each cross section of the measurement target are measured by image analysis software, and a ratio (aspect ratio) of the lateral width (or lateral dimension) to the thickness (or longitudinal dimension) is calculated. Subsequently, an average value of the aspect ratios of the measurement targets is set as an average aspect ratio.

Note that in a case in which the light-reflective member 5 contains an alkali metal, when a measurement target is a material that melts in an alkali container, the average particle diameter and the average aspect ratio of the measurement target are preferably measured before mixing with the alkali solution.

### Cap 6

The cap 6 is a light-transmissive member that transmits light emitted from the light-emitting element 3. As a material of the cap 6, an inorganic material such as sapphire and glass can be used.

The cap 6 is bonded to the upper surface 210 of the package 2 (lateral wall portion 21) by a bonding member so as to close the recessed portion 22. Examples of applicable bonding member include solder, glass, and resin. Note that the cap 6 may be bonded to the package 2 so as to seal the concave portion 22 or may be bonded to the package 2 so as not to seal the concave portion 22.

The cap 6 is rectangular in plan view. The length of each side of the cap 6 in plan view is longer than the length of each side of the inner lateral surface 221 of the recessed portion 22 (inner peripheral surface of the lateral wall portion 21). The length of each side of the cap 6 in plan view may be shorter than or approximately the same as the length of each side of an outer peripheral surface 211 of the lateral wall portion 21. The thickness of the cap 6 is in a range from 0.1 mm to 7 mm, for example. Note that the cap 6 may have a flat plate shape as in the present embodiment, or at least one of an upper surface or a lower surface thereof may have a lens shape.

As described above, in accordance with the light-emitting device 1 according to the present embodiment, the light reflecting surface 53 that reflects light emitted from the light-emitting element 3 is inclined in a direction from the inner lateral surface 221 of the recessed portion 22 toward the light-emitting element 3, and the light reflection characteristics of the light reflecting surface 53 vary depending on the height H of the light reflecting surface 53. Specifically, the light reflection characteristics of the light reflecting surface 53 in the inner peripheral edge portion 50 are different from the light reflection characteristics of the light reflecting surface 53 in the intermediate portion 52 in which the height H of the light reflecting surface 53 is higher than in the inner peripheral edge portion 50. Consequently, the light reflecting surface 53 has no uniform light reflection characteristics like a metal film, for example, and has different light reflection characteristics depending on the height H of the light reflecting surface 53, so that luminance spots of light emitted from the light-emitting device 1 can be reduced.

At this time, the reflectance of the light reflecting surface 53 is higher in the inner peripheral edge portion 50 than in the intermediate portion 52. Thus, the light-reflective member 5 can reflect light more effectively in the inner peripheral edge portion 50 on a side closer to the light-emitting element 3 than in the intermediate portion 52.

The degree of scattering (degree of diffusion) of the light reflecting surface 53 is higher in the intermediate portion 52 than in the inner peripheral edge portion 50, and the intermediate portion 52 diffuses light more than the inner peripheral edge portion 50. Thus, the light-reflective member 5 can reliably reduce luminance spots even in the intermediate portion 52 on a side farther from the light-emitting element 3 than the inner peripheral edge portion 50.

Moreover, as an example of a material for implementing the above light reflection characteristics, the light-reflective member 5 may comprise or be formed of a material including at least the first particles 54 made of a light reflecting material and the second particles 55 having a smaller average particle diameter, a lower average aspect ratio, and a lower reflectance than the first particles 54. Thus, the light reflection characteristics of the light reflecting surface 53 as described above can be implemented by a simple combination of materials. The first particles 54 function as aggregates of the light-reflective member 5 when the light-reflective member 5 is heated by heat generated from the light-emitting element 3. Thus, shrinkage of the light-reflective member 5 due to the heat of the light-emitting element 3 is suppressed, so that heat resistance of the light-emitting device 1 can be improved.

The area or the number of particles per unit area occupied by the second particles 55 in the light reflecting surface 53 is smaller in the inner peripheral edge portion 50 than in the intermediate portion 52. Therefore, the area or the number of exposed first particles 54 having a larger average particle diameter, a higher average aspect ratio, and a higher reflectance than the second particles 55 is larger in the inner peripheral edge portion 50 than in the intermediate portion 52. Thus, the light-reflective member 5 can reflect light more effectively in the inner peripheral edge portion 50 on a side closer to the light-emitting element 3 than in the intermediate portion 52, and can reliably reduce luminance spots even at the intermediate portion 52 on a side farther from the light-emitting element 3 than in the inner peripheral edge portion 50.

When the light-emitting element 3 that emits light including ultraviolet light is used, the light-reflective member 5 preferably comprises or is formed of an inorganic material. The first particles 54 comprise or are composed of, for example, at least one of boron nitride or alumina, and the second particles 55 comprise or are composed of, for example, silica. Thus, deterioration of the light-reflective member 5 due to the ultraviolet light emitted from the light-emitting element 3 can be suppressed.

Note that the light reflection characteristics of the light-reflective member 5 are derived from the surface state of the light reflecting surface 53 related to a plurality of particles having different shapes and properties; however, no such limitation is intended and the light reflection characteristics of the light-reflective member 5 can be obtained by a known method that can derive, calculate, or measure the light reflection characteristic.

### Manufacturing Method of Light-Emitting Device 1

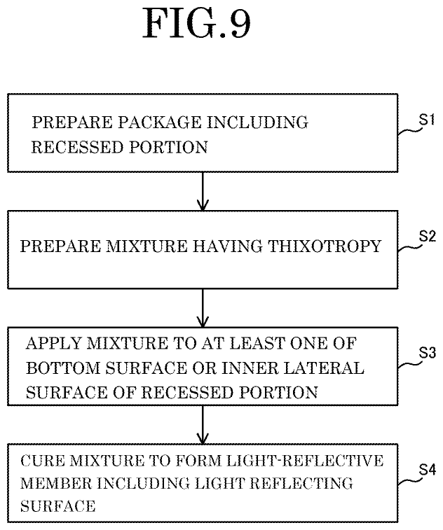

FIG. 9 is a flowchart illustrating an example of a manufacturing method of the light-emitting device 1 according to an embodiment. The manufacturing method of the light-emitting device 1 having the above configuration is described along steps S1 to S4 illustrated in FIG. 9.

### Step S1 of Preparing Package 2

First, the package 2 formed with the recessed portion 22 is prepared. The light-emitting element 3 may or may not be placed on the placement region 220a of the package 2 to be prepared. Note that when the package 2 on which the light-emitting element 3 is not placed is prepared, the light-emitting element 3 may be placed on the placement region 220a after step S4 of forming the light-reflective member 5 is performed.

### Step S2 of Preparing Mixture 7

Subsequently, at least the first particles 54 and the second particles 55 having a smaller average particle diameter, a lower average aspect ratio, and a lower total reflectance than the first particles 54 are mixed to prepare the mixture 7 having thixotropy (also referred to as thixotropic property).

For example, a mixed powder obtained by mixing the first particles 54 and the second particles 55 is mixed with an alkali solution to prepare the mixture 7. The mixed powder and the alkali solution are mixed to the extent that a uniform viscosity is obtained and are defoamed and mixed by a mixing and defoaming machine.

The first particles 54 comprise or are composed of, for example, boron nitride or alumina powder. The second particles 55 comprise or are composed of silica powder. The concentration of the alkali solution is in a range from 1 mol/L to 5 mol/L, for example. The thixotropy of the mixture 7 is adjusted by adjusting the concentration of the alkali solution with a solvent (for example, water). The viscosity characteristics of fluid representing the thixotropy of the mixture 7 can be measured by, for example, a B-type viscometer or an E-type viscometer. As the viscosity characteristics of the mixture 7, a thixotropy index (TI value) is preferably in a range from 2 to 4, for example. The thixotropy index is obtained by dividing a measured value of viscosity at a low shear rate (for example, the number of revolutions of 10 rpm) by a measured value of viscosity at a high shear rate (for example, the number of revolutions of 50 rpm). For example, the TI value can be measured using a jig with an angle of 9.7°. Note that when the light-reflective member 5 includes a scattering material, the scattering material may be mixed with the mixture 7.

### Step S3 of Applying Mixture 7

Subsequently, the mixture 7 is applied to at least one of the bottom surface 220 or the inner lateral surface 221 of the recessed portion 22 formed in the package 2.

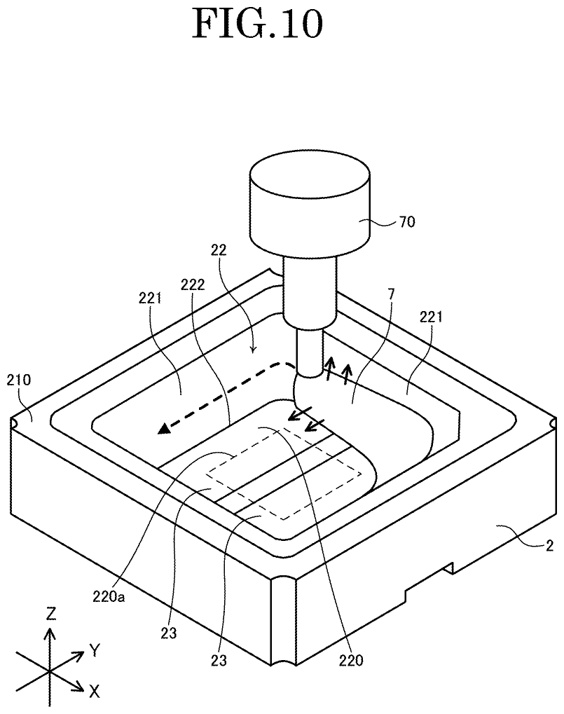

FIG. 10 is a perspective view illustrating an example of step S3 of applying the mixture 7 to the package 2. For example, the mixture 7 is applied toward the inner lateral surface 221 at a position away from the placement region 220a by using a dispensing nozzle 70 that can adjust discharge pressure and discharge diameter. At this time, the mixture 7 is continuously applied while the application position of the mixture 7 is moved along the inner lateral surface 221 so as to make one round around the light-emitting element 3 as indicated by a broken line arrow in FIG. 10. Furthermore, the mixture 7 is continuously applied to make one round around the inner lateral surface 221 while aiming at a corner portion 222 formed by the bottom surface 220 and the inner lateral surface 221. At this time, the mixture 7 is applied so that the height of the mixture 7 is in a range from ⅓ to ⅘ of a depth Hd of the concave portion 22. Thus, when the mixture 7 is cured, the mixture 7 can be suppressed from protruding upward from the upper surface 210.

As described above, when the mixture 7 is applied, the dispensing nozzle 70 may be moved in a state in which the package 2 is fixed, or the package 2 may be moved in a state in which the dispensing nozzle 70 is fixed. Note that after the mixture 7 is applied, the package 2 may be vibrated, or the mixture 7 may be applied while being vibrated. Before the mixture 7 is applied, a film may be formed on the bottom surface 220 and the inner lateral surface 221 of the recessed portion 22 by using silica, alumina, or the like. Thus, the adhesive force of the mixture 7 can be improved.

Since the mixture 7 has thixotropy, the mixture 7 immediately after being discharged from the dispensing nozzle 70 at a predetermined discharge pressure and a predetermined discharge meter and applied to the package 2 is in a state of low viscosity. Therefore, as indicated by a solid line arrow in FIG. 10, an end portion of the mixture 7 on the bottom surface 220 side immediately after application moves on the bottom surface 220 so as to approach the placement region 220a, and reaches the position of the inner peripheral edge portion 50. Furthermore, an end portion of the mixture 7 on the inner lateral surface 221 side immediately after application moves along the inner lateral surface 221 due to surface tension, and reaches the position of the outer peripheral edge portion 51. When the movement of the mixture 7 is stopped, since the viscosity characteristics of the mixture 7 transition to a state of high viscosity, the shape of the mixture 7 is maintained. The surface of the mixture 7 on the bottom surface 220 side (the inner peripheral edge portion 50 after curing) is in the same state as the state illustrated in FIG. 5. The surface of the mixture 7 between the inner lateral surface 221 side and the bottom surface 220 side (the intermediate portion 52 after curing) is in the same state as the state illustrated in FIG. 6.

### Step S4 of Forming Light-Reflective Member 5 by Curing Mixture 7

Subsequently, the mixture 7 is cured to form the light-reflective member 5 including the light reflecting surface 53 inclined in a direction from the inner lateral surface 221 of the recessed portion 22 toward the placement region 220a so as not to reach the placement region 220a.

For example, the mixture 7 is heated at a predetermined temperature and cured to form the light-reflective member 5. At this time, a temporary curing step of curing the mixture 7 at a first temperature T1 and a main curing step of curing the mixture 7 at a second temperature T2 higher than the first temperature T1 may be performed. The temporary curing step is performed at the first temperature T1 in a range from 80° C. to 100° C. for a range from 10 minutes to two hours, for example. The main curing step is performed at the second temperature T2 in a range from 150° C. to 250° C. for a range from 10 minutes to three hours, for example. By performing the temporary curing step at a temperature lower than the temperature of the main curing step, cracks in the light-reflective member 5 can be suppressed. Note that when the mixture 7 is cured, the mixture 7 may be pressurized at a predetermined pressure. Alternatively, the mixture 7 may be cured by natural drying.

Note that the above steps S1 to S4 illustrated in FIG. 9 are main steps included in the manufacturing method of the light-emitting device 1, and other steps may be included before or after each of the steps S1 to S4. Examples of the other steps include a step of placing (mounting) the light-emitting element 3 on the placement region 220a of the package 2 and a step of bonding the cap 6 to the upper surface 210 of the package 2. Each of the steps S1 to S4 may be performed in an automated manner by various devices or may be performed by an operator.

As described above, in accordance with the manufacturing method of the light-emitting device 1 according to the present embodiment, the light-emitting device 1 including the light-reflective member 5 can be manufactured by applying and curing the mixture 7 having thixotropy. At this time, the light reflecting surface 53 as the outer surface of the light-reflective member 5 is inclined with respect to the bottom surface 220 of the concave portion 22, and has different light reflection characteristics at different positions with different heights H of the light reflecting surface 53. Thus, the light-emitting device 1 including the light-reflective member 5 as described above can be manufactured by a simple method.

### OTHER EMBODIMENTS

Although the embodiment of the present invention has been described above, the present invention is not limited to the above embodiment and can be appropriately changed without departing from the technical concepts of the present invention.

The light-emitting device 1 is a device used as a light source for any application. The light-emitting device 1, for example, can be suitably used as a light-emitting device for various applications such as sterilization, disinfection, lighting, in-vehicle use, display devices, and electronic devices. The light-emitting device 1 may function not only as a single device but also in combination with other components or members.

1. A light-emitting device comprising:
a package comprising a recessed portion;
a light-emitting element placed on a bottom surface of the recessed portion at a position away from an inner lateral surface of the recessed portion; and
a light-reflective member disposed between the light-emitting element and the inner lateral surface so as to surround the light-emitting element at a position away from the light-emitting element and having a light reflecting surface configured to reflect light emitted from the light-emitting element, wherein
the light reflecting surface is inclined with respect to the bottom surface in a direction from the inner lateral surface toward the light-emitting element, and has different light reflection characteristics at different positions with different heights from the bottom surface to the light reflecting surface.

2. The light-emitting device according to claim 1, wherein
the light-reflective member is formed in contact with the bottom surface and the inner lateral surface, and
the light-reflective member includes
an inner peripheral edge portion formed on a side close to the light-emitting element,
an outer peripheral edge portion formed on a side close to the inner lateral surface, and
an intermediate portion located between the inner peripheral edge portion and the outer peripheral edge portion, and
one or more light reflection characteristic of the light reflecting surface in the inner peripheral edge portion are different from one or more light reflection characteristics of the light reflecting surface in the intermediate portion.

3. The light-emitting device according to claim 2, wherein
a reflectance of the light reflecting surface in the inner peripheral edge portion is higher than a reflectance of the light reflecting surface in the intermediate portion.

4. The light-emitting device according to claim 3, wherein
the light emitted from the light-emitting element is diffused and reflected by the light reflecting surface, and
the intermediate portion diffuses the light more than the inner peripheral edge portion does.

5. The light-emitting device according to claim 1, wherein
the light emitted by the light-emitting element includes ultraviolet light, and
the light-reflective member is formed of an inorganic material.

6. The light-emitting device according to claim 1, wherein
the light-reflective member includes at least
first particles comprising a light reflecting material, and
second particles having a smaller average particle diameter, a lower average aspect ratio, and a lower reflectance than the first particles.

7. The light-emitting device according to claim 6, wherein
the light-reflective member is formed in contact with the bottom surface and the inner lateral surface, and
the light-reflective member includes
an inner peripheral edge portion formed on a side close to the light-emitting element,
an outer peripheral edge portion formed on a side close to the inner lateral surface, and
an intermediate portion located between the inner peripheral edge portion and the outer peripheral edge portion, and
an area occupied by the second particles in the light reflecting surface in the inner peripheral edge portion is smaller than an area occupied by the second particles in the light reflecting surface in the intermediate portion, or a number of particles per unit area occupied by the second particles in the light reflecting surface in the inner peripheral edge portion is smaller than a number of particles per unit area occupied by the second particles in the light reflecting surface in the intermediate portion.

8. The light-emitting device according to claim 6, wherein
the light emitted by the light-emitting element includes ultraviolet light,
the light-reflective member is formed of an inorganic material,
the first particles comprise at least one of boron nitride or alumina, and
the second particles comprise silica.

9. The light-emitting device according to claim 1, wherein
the light-reflective member has an asymmetrical shape.

10. The light-emitting device according to claim 1, wherein
the light-reflective member includes the light reflecting surface formed in a concave shape with respect to the bottom surface or the light reflecting surface formed in a convex shape with respect to the bottom surface.

11. A method of manufacturing a light-emitting device, the method comprising:
preparing a package including a recessed portion comprising an inner lateral surface and a bottom surface having a placement region on which a light-emitting element is placeable;
mixing at least first particles comprising a light reflecting material and second particles having a smaller average particle diameter than the first particles, a lower average aspect ratio than the first particles, and a lower total reflectance than the first particles, to prepare a mixture having thixotropy;
applying the mixture to at least one of the bottom surface or the inner lateral surface; and
curing the mixture to form a light-reflective member comprising a light reflecting surface inclined with respect to the bottom surface in a direction from the inner lateral surface toward the placement region so as not to reach the placement region.

12. The light-emitting device according to claim 1, wherein
the light-emitting element emits ultraviolet light, and
the light-reflective member comprises an inorganic material.

13. The light-emitting device according to claim 6, wherein
the light emitted by the light-emitting element includes ultraviolet light,
the light-reflective member comprises an inorganic material.
